(19) United States
(12) Patent Application Publication
(10) Pub. No.: US 2014/0034893 A1
(43) Pub. Date: Feb. 6, 2014

(54) SWITCH DEVICE AND CROSSBAR MEMORY ARRAY USING SAME

(71) Applicant: TOKYO ELECTRON LIMITED, Minato-ku (JP)

(72) Inventors: Hajime NAKABAYASHI, Yamanashi (JP); Yoshihiro HIROTA, Yamanashi (JP)

(73) Assignee: TOKYO ELECTRON LIMITED, Minato-ku (JP)

(21) Appl. No.: 13/957,795

(22) Filed: Aug. 2, 2013

(30) Foreign Application Priority Data
Aug. 2, 2012 (JP) 2012-171839

(51) Int. Cl. H01L 45/00

(52) U.S. Cl. CPC H01L 45/144
USPC 257/2

(57) ABSTRACT

A switch device used in a crossbar memory array having a non-volatile memory includes: a laminated body formed of a semiconductor film and an insulating film laminated on the semiconductor film; and a pair of electrode layers having the laminated body therebetween. The semiconductor film is made of a semiconductor material having an I-V characteristic with a negative resistance region.

### CROSS-REFERENCE TO RELATED APPLICATIONS

This application claims priority to Japanese Patent Application No. 2012-171839 filed on Aug. 2, 2012, the entire contents of which are incorporated herein by reference.

### FIELD OF THE INVENTION

The present invention relates to a switch device used in a crossbar memory array having a non-volatile memory and the crossbar memory array using the switch device.

### BACKGROUND OF THE INVENTION

Non-volatile memory devices such as flash memory have been widely used, but they presented limits in its capacity, speed, and longevity. Therefore, as a new non-volatile memory, which can overcome such limitations, a state-change memory has been attracting more attention in recent years. As a state-change memory, there is, for example, a phase-change random access memory (PRAM) that stores information by using a phase-change film (see, e.g., U.S. Patent Application Publication No. 2009/0057642). The phase-change film is formed of a material having two phases: a phase of an amorphous state that involves heating the phase-change film to a high temperature (600° C. or higher, for example) and then rapidly cooling it, thereby turning it into an amorphous state having a high resistance value; and a phase of a crystalline state that involves heating the phase-change film to a low temperature (400° C. or higher, for example) and then slowly cooling it, thereby turning it into a crystalline state having a usual resistance value. The PRAM stores data using the resistance difference of the two phases of the phase-change film.

In the case where the state-change memory such as the phase-change memory is used in a crossbar memory array, a switch device is required, in addition to the memory devices, for selecting a memory device by blocking stray currents which reduce a sensing margin.

As the switch device, there is known a two-terminal switch device which utilizes rectification of p-n junctions including Si PIN diodes. Further, there is also known an ovonic threshold switch (OTS) which utilizes threshold switching characteristics shown from chalcogenide having a low crystallizability (see U.S. Patent Application Publications Nos. 2011/0149628 and 2012/0002461).
Patent Document 1: U.S. Patent Application Publication No. 2009/0057642
Patent Document 2: U.S. Patent Application Publication No. 2011/0149628
Patent Document 3: U.S. Patent Application Publication No. 2012/0002461

However, in the two-terminal switch device which utilizes rectification of p-n junctions, the on-resistance is as high a value as mΩcm² and a sufficiently low on-resistance is not obtained in minute junction areas of a miniaturized device. Further, a high on/off resistance ratio is not obtained and a switching movement is also insufficient. Furthermore, even though in OTS, on-resistance is low, there are problems in that a turn-on threshold voltage is smaller than 1V, which is a low value, and a pressure-resistance is also low.

### SUMMARY OF THE INVENTION

In view of the above, the present invention provides a switch device having a low on-resistance, a high on/off resistance ratio, a high switching speed, a relatively high turn-on threshold voltage, and a high pressure-resistance, and a crossbar memory array using the switch device.

In accordance with a first aspect of the present invention, there is provided a switch device used in a crossbar memory array having a non-volatile memory, the switch device including: a laminated body formed of a semiconductor film and an insulating film laminated on the semiconductor film, the semiconductor film made of a semiconductor material having an I-V characteristic with a negative resistance region; and a pair of electrode layers having the laminated body therebetween.

Further, the semiconductor film may be made of chalcogenide. The chalcogenide may be GeSbTe. The insulating film may be an oxide film. The oxide film may be an SiO₂ film. The semiconductor film may be formed by ALD.

In accordance with a second aspect of the present invention, there is provided a crossbar memory array, including: a plurality of first wirings provided parallel to each other; a plurality of second wirings provided parallel to each other and orthogonal to the first wirings when seen from the top; and a plurality of layered structures provided at orthogonal intersections between the first wirings and the second wirings, each including a non-volatile memory device and a switch device stacked on the non-volatile memory device, wherein the switch device includes: a laminated body formed of a semiconductor film and an insulating film laminated on the semiconductor film, the semiconductor film made of a semiconductor material having an I-V characteristic with a negative resistance region; and a pair of electrode layers having the laminated body therebetween.

Further, the non-volatile memory device may have a memory layer made of phase-change material. The semiconductor film of the switch device and the memory layer of the non-volatile memory device may be formed of chalcogenide. The chalcogenide may be GeSbTe.

Further, the semiconductor film of the switch device and the memory layer of the non-volatile memory device may be formed by ALD.

### Effect of the Invention

In accordance with the present invention, a switch device includes a laminated body formed of a semiconductor film having a negative resistance region and an insulating film serving as a variable resistor with low resistance, by F-N tunneling, at high voltage. Accordingly, the switch device can obtain a low on-resistance, a high off-resistance, and excellent switching characteristics with a high on/off resistance ratio. Further, due to the presence of the insulating film, a threshold voltage Vₜₕ can be adjusted and a pressure-resistance can be improved. Furthermore, the switch device can operate in a high speed by miniaturizing its structure, since the speed of the switch device is determined by a relaxation time defined as the product of the capacitance of the switch device and the resistance of the insulating film.

### DETAILED DESCRIPTION OF THE DRAWINGS

The objects and features of the present invention will become apparent from the following description of embodiments, given in conjunction with the accompanying drawings, in which:

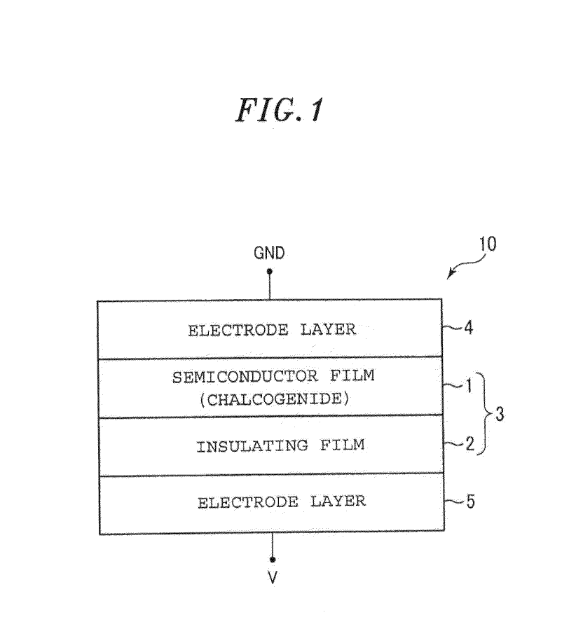

FIG. 1 is a cross-sectional view showing a switch device in accordance with an embodiment of the present invention;

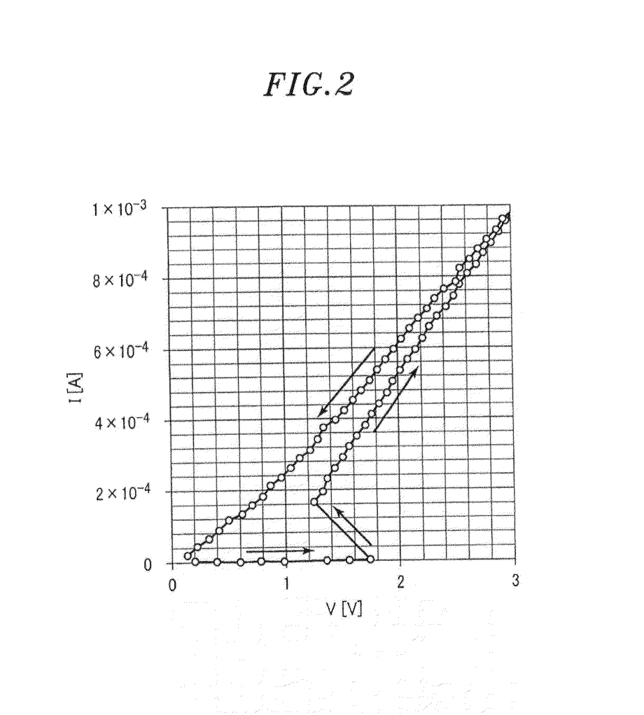

FIG. 2 shows the I-V characteristic of GeSbTe film;

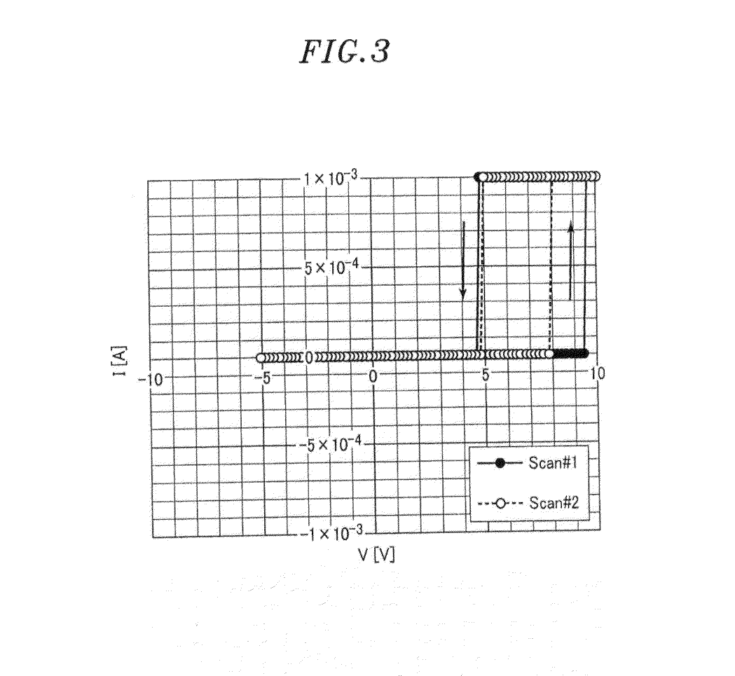

FIG. 3 shows I-V characteristic curves indicating switching characteristics of the switch device of the present embodiment, wherein a current value in the vertical axis is depicted on a normal scale;

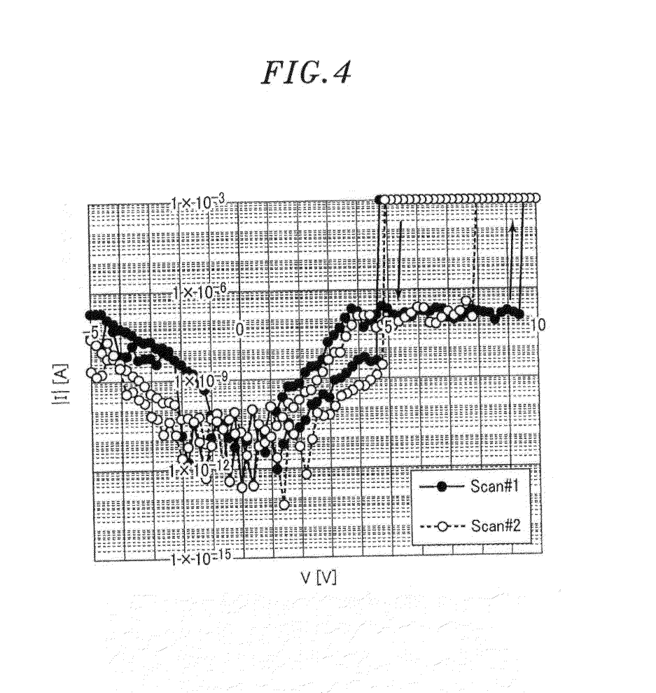

FIG. 4 shows I-V characteristic curves indicating switching characteristics of the switch device of the present embodiment, wherein a current value in the vertical axis is depicted on a logarithmic scale;

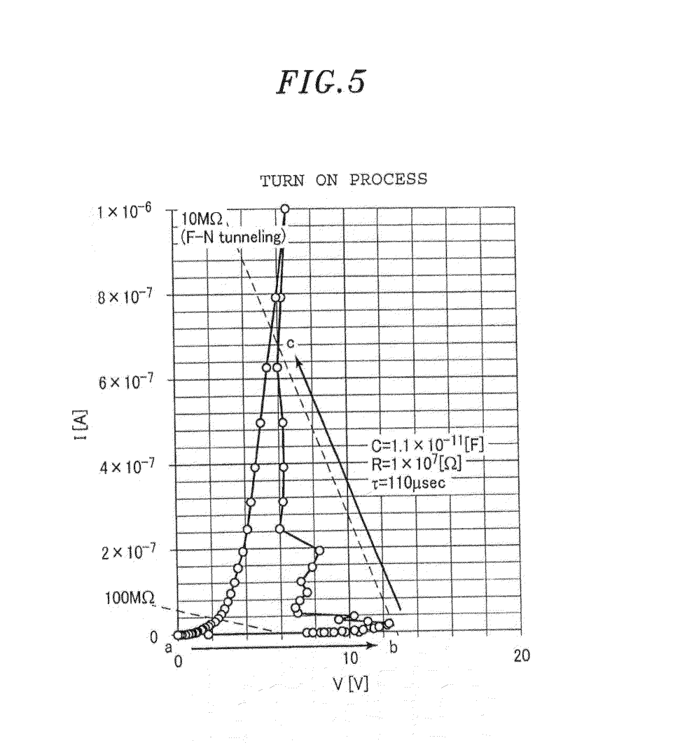

FIG. 5 is a graph for explaining a turn-on process, which shows an IV characteristic of the switch device of the present embodiment;

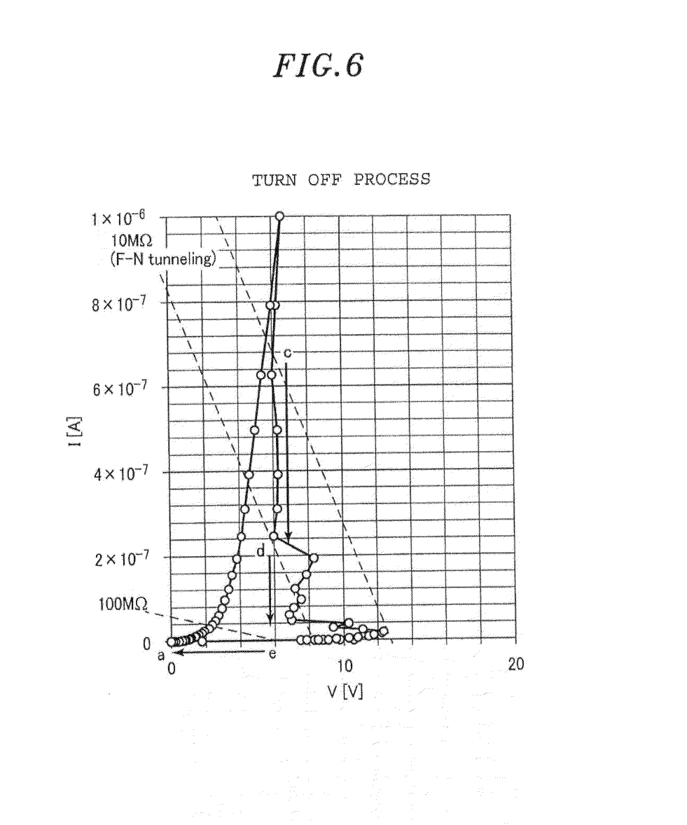

FIG. 6 is a graph for explaining a turn-off process, which shows an IV characteristic of the switch device of the present embodiment;

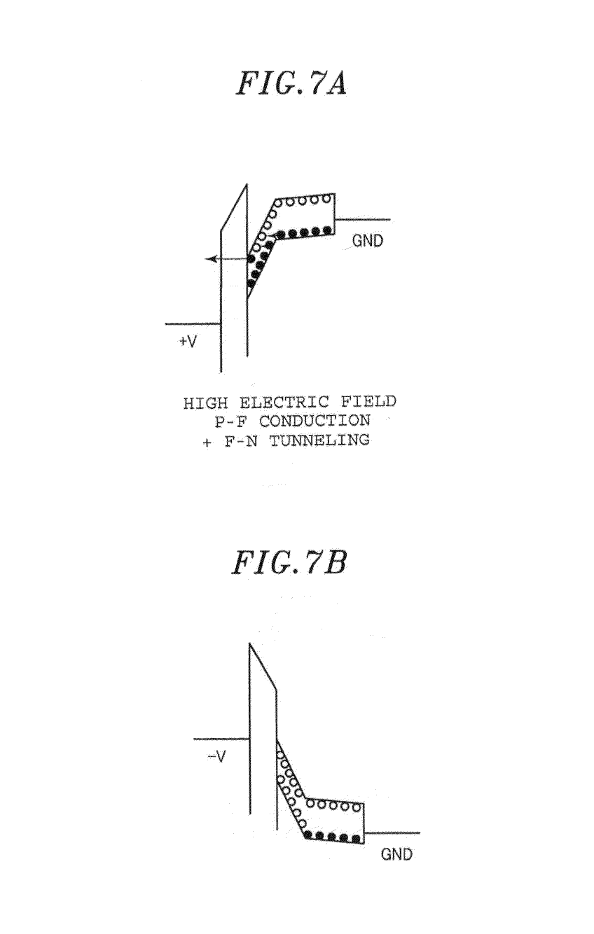

FIGS. 7A and 7B are views showing energy bands for explaining the rectification of the switch device of the present embodiment;

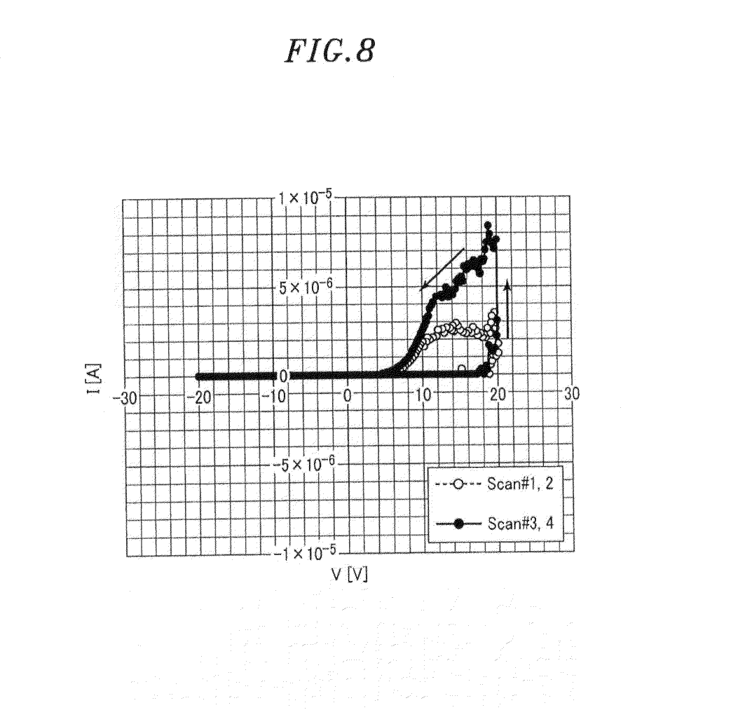

FIG. 8 shows I-V characteristic curves for explaining the rectification of the switch device of the present embodiment;

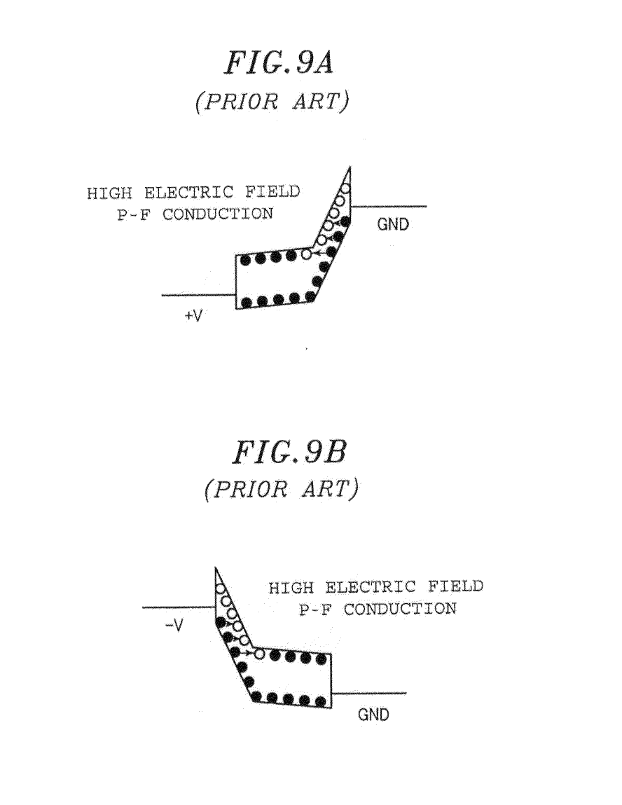

FIGS. 9A and 9B are views showing energy bands of a switch device in the OTS disclosed in US 2012/0002461 A1 (Patent Document 3) as a comparative example;

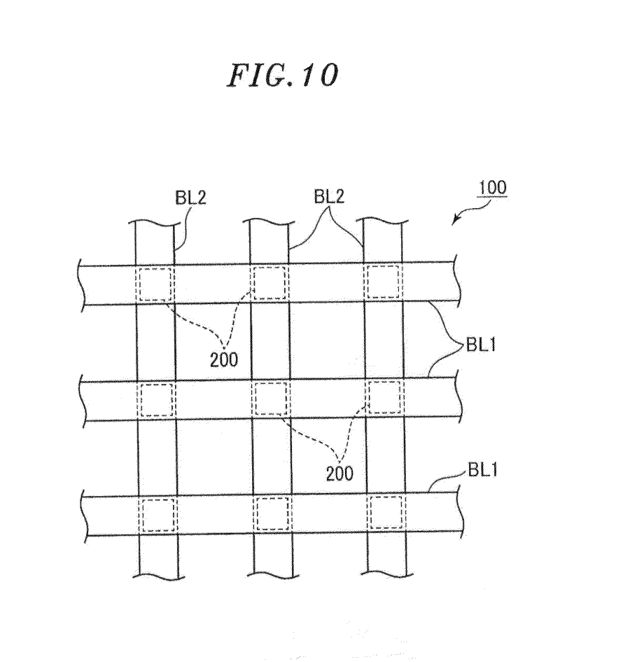

FIG. 10 is a plan view showing an example of a crossbar memory array to which the switch device of the present embodiment is applied;

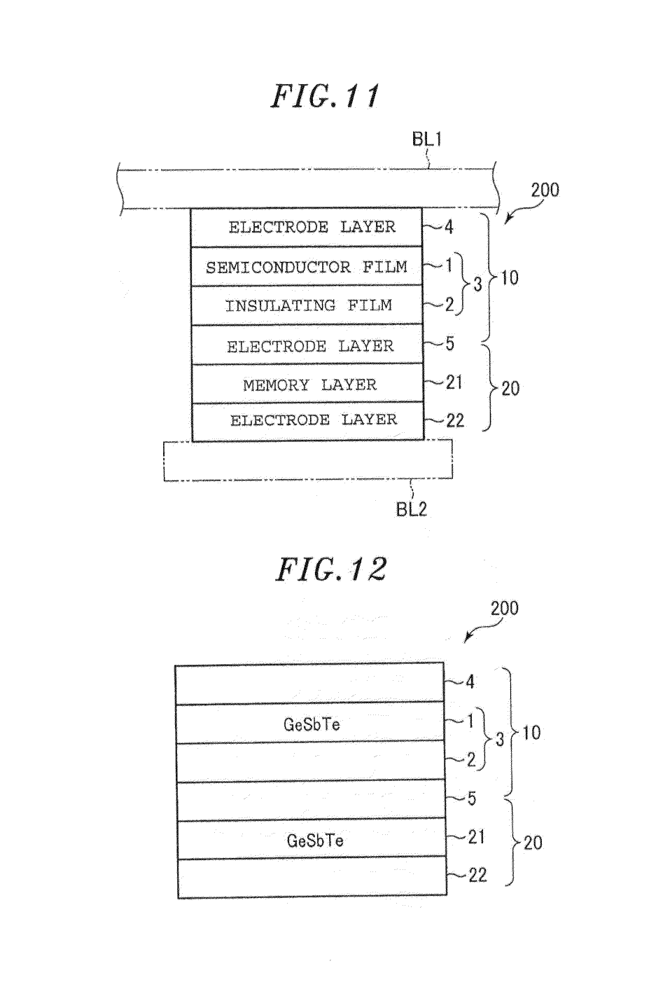

FIG. 11 is a cross-sectional view showing a laminated structure in which the switch device of the present embodiment is stacked on a non-volatile memory device in the crossbar memory array of FIG. 10; and

FIG. 12 is a cross-sectional view showing, in the laminated structure in which the switch device of the present embodiment is stacked on the non-volatile memory device in the crossbar memory array of FIG. 10, a case where GeSbTe is used for both the semiconductor layer of the switch device and the memory layer of the non-volatile memory device.

### DETAILED DESCRIPTION OF THE EMBODIMENTS

Hereinafter, an embodiment of the present invention will be described in detail with reference to the accompanying drawings which form a part hereof.

(Configuration of Switch Device)

FIG. 1 is a cross-sectional view showing a switch device in accordance with an embodiment of the present invention.

In the present embodiment, a switch device 10 is a two-terminal device having 4-layer structure in which a laminated body 3 formed of a semiconductor film 1 and an insulating film 2 is interposed between electrode layers 4 and 5.

The semiconductor film 1 has a switch function and is made of a semiconductor material having an I-V characteristic with a negative resistance region. A chalcogenide is a representative semiconductor material having the I-V characteristic. FIG. 2 shows an I-V characteristic of GeSbTe film which is a typical chalcogenide, wherein the GeSbTe film has been formed by a physical vapor deposition (PVD). As shown in FIG. 2, a snap-back occurs near 1.8V, and a ‘S’-shaped I-V characteristic has the negative resistance region representing a negative differential resistance (NDR). A snapback voltage is defined as a threshold voltage Vₜₕ.

As the chalcogenide having the I-V characteristic, there are AsSbTe, InSbTe, InSb, SnSbTe, and the like, aside from GeSbTe.

The insulating film 2 functions as a voltage variable resistor depending on a bias voltage by being laminated with the semiconductor film 1 and has a high resistance at low voltage and a low resistance, by the Fowler-Nordheim (F-N) tunneling, at high voltage, which contributes to a high off-resistance and a low on-resistance.

The insulating film 2 is preferably an oxide film such as SfO₂, HfO₂, ZrO₂, Ta₂O₅, TiO₂, Al₂O₃, or the like in terms of effectively demonstrating the characteristics. Additionally, a nitride layer such as SiN or a semiconductor such as Ge may be used as the insulating film 2.

The electrode layers 4 and 5 may preferably use TiN, Ti, Ta, TaN, W, and the like, but are not limited to those if the electrode layers 4 and 5 are able to supply power to the laminated body 3 formed of the semiconductor film 1 and the insulating film 2.

(Manufacturing Method of Switch Device)

In order to manufacture the switch device 10, the electrode layer 5 is formed on a substrate by a physical vapor deposition (PVD) such as sputtering, a chemical vapor deposition (CVD), or an atomic layer deposition (ALD); then atop the electrode layer 5, the insulating film 2 is formed by PVD, CVD, or ALD; then the semiconductor film 1 is formed on the insulating film 2 by PVD, CVD, or ALD; and lastly, atop the semiconductor film 1, the electrode layer 4 is formed by PVD, CVD, or ALD. The film thicknesses are set appropriately according to manufacturing conditions, device geometry and dimensions, materials, and the like. Of these films, the thickness of the semiconductor film 1 can be in the range of, e.g., 10 to 50 nm. Further, the thickness of the insulating film 2 is preferable to be 1 nm or more for serving as a variable resistor. The upper limit of the thickness of the insulating film 2 can be defined from the condition where, e.g., a parasitic resistance for 100 nm×100 nm junction becomes smaller than 1 GΩ.

The semiconductor layer 1 is preferably formed by ALD which has a good step coverage. In the case of forming the GeSbTe film by ALD, e.g., a deposition of a thin Ge film by using a gas form of Ge material and a reactive gas, a deposition of a thin Sb film by using a gas form of Sb material and a reactive gas, and a deposition of a thin Te film by using a gas form of Te material and a reactive gas are repeated by turns. In this regard, a detailed deposition method disclosed in, e.g., Japanese Patent Application No. 2011-179981 may be adopted.

(Switching Characteristics)

Switching characteristics of the switch device 10 of the present embodiment will now be described. FIGS. 3 and 4 show I-V characteristic curves indicating the switching characteristics of the switch device 10, wherein a 50 nm thick GeSbTe film deposited by ALD is used as the semiconductor film 1; a 100 nm thick SiO₂ film deposited by PVD is used as the insulating film 2; and a 50 nm thick TiN film deposited by PVD is used as the electrode layers 4 and 5. In FIG. 3, a current value in the vertical axis is depicted on a normal scale, and in FIG. 4, it is depicted on a logarithmic scale. Here, the curves has been derived by performing multiple times a voltage sweep of which one cycle includes a forward sweep from −5V to +10V and a reverse sweep from +10V to −5V. In FIGS. 3 and 4, Scan#1 indicates the measurement result of the first cycle and Scan#2 indicates the measurement result of the second cycle. In the forward sweep, during which a positive voltage applied to the switch device 10 at an initial high resistance state is increased, a steep increase in the current value is shown near +9V. After that, when the reverse sweep is performed from +10V to −5V, a steep decrease in the current value is shown near +5V, and the I-V characteristic shows hysteresis behavior. The steep increase in the current value in the forward sweep represents turn-on of the switch device 10 and the steep decrease in the current value in the reverse sweep represents turn-off of the switch device 10. The on-current value is 1 mA, which reaches a current limit value for the device protection. As shown in FIG. 4, the off (0V)-current value is 10pA, and an on/off resistance ratio is more than 10⁸, which is an extremely large value. Further, since the change in the current at turn-on and turn-off time is steep, very good switching characteristics is obtained. The size of the hysteresis can be adjusted by the material, the thickness, and the like of the insulating film 2.

(Operation Principles of Switch Device)

Next, the principles of operation of the switch device will be described in accordance with the present embodiment.

FIGS. 5 and 6 show I-V characteristic curves of the switch device 10, wherein a 50 nm thick GeSbTe film deposited by ALD is used as the semiconductor film 1; a 100 nm thick SiO₂ film deposited by PVD is used as the insulating film 2; and a 50 nm thick TiN film deposited by PVD is used as the electrode layers 4 and 5. FIG. 5 is a graph for explaining a turn-on process, and FIG. 6 is a graph for explaining a turn-off process.

The switch device 10 of the present embodiment, as compared with the I-V characteristic of GeSbTe in FIG. 2, is characterized by an extremely high threshold voltage Vₜₕ of 12V. The reason for the high Vₜₕ is because of the effect of the potential drop caused by a high resistance of the SiO₂ film. As a result, the pressure-resistance is high. In addition, it is considered possible to decrease the Vₜₕ by thinning the insulating film 2.

The progress of an operating point in the turn-on process is shown in FIG. 5. The GeSbTe film has a high resistance at an initial state (0V; point ‘a’). When an applied voltage increases from 0V and reaches Vₜₕ (point ‘b’) near 12 V, a current in the GeSbTe film rapidly increases due to the P-F (Poole-Frenkel) conduction in a high electric field. Accordingly, the negative resistance region, in which a voltage applied to the GeSbTe film is decreased, is formed. The current flowing through the switch device 10 is limited by a load resistance of the SiO₂ film serving as the insulating film 2, and the operating point shifts from point ‘b’ to point ‘c’. In a transition course from point ‘b’ to point ‘c’, the switch device 10 acts as a capacitor, so that it is discharged when the current of the switch device 10 is limited by the resistance of the SiO₂ film. Accordingly, the resistance of the switch device 10 is rapidly lowered. Therefore, a period of time required to the transition from point ‘b’ to point ‘c’ is approximately a relaxation time, which is defined as the product of the resistance of the SiO₂ film and the capacitance of the switch device 10, and this is a factor in determining a switching speed.

As such, because the relaxation time is determined by multiplying the resistance of the SiO₂ film and the capacitance of the switch device 10, the switch device 10 can operate in a high speed by miniaturizing its structure. In this example, it is estimated that an area of an upper electrode is 31200 μm² and the relaxation time is about 110 μsec. Therefore, by reducing the area of the switch device 10 up to 1 μm², it is expected to shorten the relaxation time by up to 4 nsec. At this time, due to the SiO₂ film serving as the insulating film 2 becoming low resistance by the F-N tunneling at high voltage, a low on-resistance is obtained.

The progress of an operating point in the turn-off process is shown in FIG. 6. The operating point shifts from point ‘c’ to point ‘d’ near 6V, as a terminal voltage is lowered. Point ‘d’ is the lowest voltage representing the negative resistance region, at which the high electric field P-F conduction stops in GeSbTe film. As the high electric field P-F conduction stops, the GeSbTe film returns to the high resistance state and the operation point shifts from point ‘d’ to point ‘e’. This transition from point ‘d’ to point ‘e’ is the reason for the sharp increase in the resistance of the GeSbTe film at turn-off. In addition, when the voltage is further lowered, the operating point shifts from point ‘e’ to point ‘a’ at the plot of the high resistance state and the switch device 10 turns off.

As described above, according to the switch device 10 of the present embodiment, by the presence of the semiconductor film 1 having the negative resistance region and the insulating film 2 serving as a variable resistor with low resistance, by F-N tunneling, at high voltage, it is possible to have a low on-resistance and a high off-resistance and obtain excellent switching characteristics with a high on/off resistance ratio. Further, by the presence of the insulating film 2, the Vₜₕ can be adjusted and the pressure-resistance can be improved. Furthermore, because the speed of the switch device 10 is determined by the relaxation time, which is defined as the product of the capacitance of the switch device 10 and the resistance of the insulating film 2, the switch device 10 can operate in a high speed by miniaturizing its structure.

(Rectification of the Switch Device)

The switch device 10 of the present embodiment is formed by laminating the insulating film 2 on the semiconductor film 1 having the negative resistance region represented as chalcogenide. The switching of the switch device 10 is performed by using the P-F conduction in a high electric field and the F-N tunneling at high voltage. As shown in FIGS. 7A and 7B, the high electric field P-F conduction is formed only when a positive voltage is applied to the insulating film 2 side and the semiconductor film 1 side is in an inverted state, to thereby start the switching operation. Such switching characteristics, as shown in FIG. 8, show rectification. In FIG. 8, Scan#1 indicates the first measurement result by increasing the positive voltage applied to the switching device 10, Scan#2 indicates the first measurement result by decreasing the positive voltage applied to the switching device 10, Scan#3 indicates the second measurement result by increasing the positive voltage applied to the switching device 10, and Scan#4 indicates the second measurement result by decreasing the positive voltage applied to the switching device 10.

The OTS disclosed in US 2012/0002461 A1 has a structure having the chalcogenide film being interposed between electrodes. Accordingly, as shown in FIGS. 9A and 9B, the OTS does not show rectification since the high electric field P-F conduction is formed regardless of the bias polarity.

(Adjustment of the Threshold Voltage)

In the switch device 10 of the above structure, the voltage applied to the semiconductor film 1 is determined by the resistance ratio of the semiconductor film 1 and the insulating film 2. By utilizing this effect, a voltage value at which the applied voltage of the semiconductor film 1 reaches the threshold voltage Vₜₕ can be controlled. In the case of using the Si PIN diodes disclosed in US 2011/0149628 A1 (Patent Document 2) or the OTS disclosed in US 2012/0002461 A1 as a switch device, since the threshold voltage is determined by the material properties, the switch device generally has a turn-on voltage of 1V or less, and cannot control the threshold voltage V. Thus, the switch device 10 of the above structure has a great advantage of being able to control the threshold voltage Vₜₕ by the thickness ratio of the semiconductor film 1 and the insulating film 2.

(Process Temperature)

For the switch device 10 of the present embodiment, in the case when the insulating film 2 and the electrode layers 4 and 5 are deposited by PVD and the semiconductor film 1 is deposited by ALD or CVD, the film depositions may be performed at room temperature or at a relatively low temperature even if accompanied by heat. In the case of using chalcogenide as the semiconductor film 1, a process requiring the highest temperature is a crystallization anneal of the chalcogenide, and the temperature is only about 300° C. On the contrary, in the case of using the Si PIN diodes as a switch device, a relatively high temperature of 900° C. is required for the thermal diffusion process. Therefore, it is possible, in the present embodiment, to manufacture the switch device 10 using low temperature processes, compared to the case of using the Si PIN diodes as the switch device.

(Crossbar Memory Array)

Next, a crossbar memory array to which the switch device of the present embodiment is applied will be described. FIG. 10 is a plan view showing a crossbar memory array to which the switch device of the present embodiment is applied. FIG. 11 is a cross-sectional view showing a structure of the switch device of the present embodiment laminated on a memory device.

As shown in FIG. 10, a crossbar memory array 100 includes a plurality of upper wirings BL1 and a plurality of lower wirings BL2, which are provided in orthogonal patterns when seen from the top. As shown in FIG. 11, a layered structure 200, which includes the switch device 10 stacked on top of a non-volatile memory device 20, is disposed at every these orthogonal intersections between the upper wirings BL1 and the lower wirings BL2.

The non-volatile memory device 20 includes a memory layer 21 for storing information and electrode layers 5 and 22. The electrode layer 5 is common with one of the electrode layers of the switch device 10. FIG. 11 shows, for convenience, a film-shaped memory layer 21, but in fact, the shape may take various forms such as a rod-shape or the like.

GeSbTe is typically used for the memory layer 21 as a state-change material, for example, a phase-change material that changes phase between an amorphous state and a crystalline state. It may be mentioned that Ge₂Sb₂Te₅ is a representative composition of GeSbTe. By using the phase-change material as the memory layer 21, a non-volatile PRAM, which uses a change in resistance between the amorphous and the crystalline state, is produced. Other than the phase-change material, the memory layer 21 may use a resistance-change material, which stores information by a resistance change by using, e.g., metal oxides such as Ta₂O₅, HFO₂, NiO, and the like. A non-volatile resistive memory device (RRAM™) is produced by using the resistance-change material as the memory layer 21.

In the switch device 10 of the present embodiment, the semiconductor film 1 having the negative resistance region exhibits switching characteristics in synergy with the insulating film 2 serving as a variable resistor by having low resistance, by the F-N tunneling, at high voltage. Accordingly, the range of choices in the materials of the semiconductor film 1 is wide. As shown in FIG. 12, in the case of using GeSbTe for the memory layer 21 of the memory device 20, the semiconductor film 1 of the switch device 10 may use the same GeSbTe as the memory layer 21. Accordingly, in the case of manufacturing the memory device 20 and the switch device 10 in a batch, the semiconductor film 1 and the memory layer 21 can be formed in the same chamber and the production can be simplified. Also, in this case, if the semiconductor film 1 and the memory layer 21 are the same GeSbTe, their compositions may be different.

When using the OTS disclosed in US 2012/0002461 A1, since the range of selection in the material of the chalcogenide film is limited and a special material that is difficult to crystallize, e.g., such as Te—As—Si—Ge is required, the chalcogenide film cannot use the same material as the memory layer. For this reason, when manufacturing the memory device and the switch device in a batch, the chalcogenide film and the memory layer need to be produced in individual chambers.

Therefore, the switch device 10 of the present embodiment is also advantageous over the technique disclosed in US 2012/0002461 A1 from the standpoint of manufacturing simplicity.

While the invention has been shown and described with respect to the embodiments, it will be understood by those skilled in the art that various changes and modifications may be made without departing from the scope of the invention as defined in the following claims.

What is claimed is:

1. A switch device used in a crossbar memory array having a non-volatile memory, the switch device comprising:
a laminated body formed of a semiconductor film and an insulating film laminated on the semiconductor film, the semiconductor film made of a semiconductor material having an I-V characteristic with a negative resistance region; and
a pair of electrode layers having the laminated body therebetween.

2. The switch device of claim 1, wherein the semiconductor film is made of chalcogenide.

3. The switch device of claim 2, wherein the chalcogenide is GeSbTe.

4. The switch device of claim 1, wherein the insulating film is an oxide film.

5. The switch device of claim 4, wherein the oxide film is an SiO₂ film.

6. The switch device of claim 2, wherein the insulating film is an oxide film.

7. The switch device of claim 6, wherein the oxide film is an SiO₂ film.

8. The switch device of claim 3, wherein the insulating film is an oxide film.

9. The switch device of claim 8, wherein the oxide film is an SiO₂ film.

10. The switch device of claim 1, wherein the semiconductor film is formed by ALD.

11. A crossbar memory array, comprising:
a plurality of first wirings provided parallel to each other;
a plurality of second wirings provided parallel to each other and orthogonal to the first wirings when seen from the top; and
a plurality of layered structures provided at orthogonal intersections between the first wirings and the second wirings, each including a non-volatile memory device and a switch device stacked on the non-volatile memory device, wherein the switch device includes:
a laminated body formed of a semiconductor film and an insulating film laminated on the semiconductor film, the semiconductor film made of a semiconductor material having an I-V characteristic with a negative resistance region; and
a pair of electrode layers having the laminated body therebetween.

12. The crossbar memory array of claim 11, wherein the non-volatile memory device has a memory layer made of phase-change material.

13. The crossbar memory array of claim 12, wherein the semiconductor film of the switch device and the memory layer of the non-volatile memory device are formed of chalcogenide.

14. The crossbar memory array of claim 13, wherein the chalcogenide is GeSbTe.

15. The crossbar memory array of claim 11, wherein the semiconductor film of the switch device and the memory layer of the non-volatile memory device are formed by ALD.
